(19) United States
(12) Patent Application Publication
(10) Pub. No.: US 2012/0037935 A1
(43) Pub. Date: Feb. 16, 2012

(54) Substrate Structure of LED (light emitting diode) Packaging and Method of the same

(75) Inventor: Wen-Kun Yang, Hsin-Chu City (TW)

(73) Assignee: Wen-Kun Yang, Hsin-Chu City (TW)

(21) Appl. No.: 12/855,706

(22) Filed: Aug. 13, 2010

(51) Int. Cl. H01L 33/48; H01L 33/00

(52) U.S. Cl. 257/98; 438/29; 257/E33.056; 257/E33.001

(57) ABSTRACT

The present invention provides a substrate for LED packaging and a fabrication method thereof. The substrate can dissipate heat quickly and enhance light emitting efficiency. For this purpose, several via holes are formed in the substrate and metal layers are coated to act as light reflector. In the substrate, the via holes are filled with the material with high thermal conductivity, such as Copper, to conduct the heat efficiently; and the reflector are coated the metal with high reflection factor to visible light, such as Ag, Au, Al, to enhance the light emitting efficiency.

### BACKGROUND

1. Technical Field

This invention relates to a substrate structure for an LED packaging, and more particularly to a substrate structure which can dissipate heat efficiently, and thus improve the light conversion efficiency and the lifespan of the LED.

2. Description of the Related Art

LED is more and more used in many applications, such as lighting, display, indicator etc. LED is a semiconductor device wherein electrical energy is directly converted into optical energy, within a very narrow wavelength range. The light output of an LED is proportional to the forward current which is the function of forward voltage applied.

While in operation, only about 20% of electrical energy applied to LED is converted to visual light and the rest of energy, about 80%, is converted to heat. Given that the heat cannot dissipate immediately, the junction temperature of the semiconductor device will increase; and the higher junction temperature is, the lower of light emitting efficiency and the shorter of lifetime of LED will be. Theoretically, the lifetime of LED will increase 1.9 times as the junction temperature lower 10 degrees centigrade. Besides, the increased temperature will also change the wavelength of light emitted by LED, which is not wanted in applications.

Therefore, the package design of LED is a key contributor to produce better discrete component designs that can perform more efficiently in a wide variety of operational and environmental conditions with higher performance and higher brightness applications. It is crucial to divert the heat generated from LED to the path with high thermal conductivity. Most conventional packages existing to date are inadequate for the demands of many current and future LED applications. The structure of conventional LED packaging consists of LED chip, die attach material, substrate, heat sink, mounting material and metal core board. Every element in the thermal conduction path contributes to the total thermal resistance.

The industrial roadmap for LED identifies three areas of technological improvements in packaging. The three areas are: 1. Materials that increase the extraction efficiency of the light from the LED die; 2. Optics that improve the extraction of light from the final package; 3. Thermal management of the LED die and lighting system.

Most current LED packages use ceramic substrate, such as Al₂O₃, AlN, and those need heat sink to dissipate the power efficiently due to the poor thermal conductivity of ceramics. In order to improve the light emitting efficiency of the packaged LED, metal mirrors begin to be adopted commonly. The main purpose of the mirror is to collect light and steer it to another location in the optical system. A LED package with a well-designed metal mirror not only improves the light emitting efficiency of the whole package, but also reduces the heat generated from the un-emitted light.

### SUMMARY

The present invention provides a substrate structure for a LED packaging to overcome the aforementioned problems in the prior art. The substrate has the structure with plurality of Copper (Cu) filled via holes to conduct heat more efficiently and with the cavity metal as a reflector to enhance the light emitting efficiency.

The object of the present invention is to provide a substrate with simple structure and excellent capability of thermal dissipation for LED packaging to increase the energy to light conversion efficiency and the lifespan of LED.

The further object of the present invention is to provide a substrate with metal reflectors to improve the light emitting efficiency of LED packaging.

The present invention discloses a structure of substrate comprising: a first substrate with a die metal pad, a plurality of Cu-filled via holes under the die metal pad, and wiring circuits on the top and bottom surface of the first substrate; a second substrate with a die opening window, and wiring circuits on the top and bottom surface of the second substrate; an adhesive material between the top of the first substrate and the bottom of the second substrate except the die opening window; a cavity metal covering on the wall of the die opening window of the second substrate and the top side of the die metal pad of the first substrate within the die opening window; and a plurality of through holes connecting both wiring circuits of the first and second substrate.

According to a certain embodiment of the invention, the inner wall of said through holes are coated with conductive metal.

According to a certain embodiment of the invention, the material of conductive metal on the inner wall of said through holes includes Cu/Ni/Au, Cu/Ni/Ag and Cu/Ni/Al;

According to a certain embodiment of the invention, the material of the wiring circuits on the first and second substrate includes Cu, Al or the combination thereof; the material of the die metal pad on the first substrate includes Cu, Al or the combination thereof; the material of said cavity metal includes Ag, Au, and Al; and the material of said first and second substrate includes BT, FR5, FR4 PCB (printed circuit board), silicon, Glass, ceramic and metal.

The present invention further discloses a packaged LED comprising: a die attached material filled into the die opening window; a LED chip attached, with external force, into the die opening window and on the die metal pad of the first substrate; a plurality of wires or RDL electrically connecting between the metal pads of the LED chip and the wiring circuit on top of the second substrate; a lens and/or protection layer attached on top of the second substrate.

According to a certain embodiment of the invention, the thickness of said die attached material between the backside of the LED chip and the top of the die metal pad is around 10 um˜30 um.

The present invention further discloses a method of forming a substrate for LED packaging comprising: preparing the pre-made first substrate with a die metal pad on top side, a plurality of via holes under the area of the die metal pad, and wiring circuits on both side; preparing the pre-made second substrate with wiring circuits on both side; Using Puncher or Laser to form the die opening window on the second substrate; placing the photo-sensitive adhesion layer between the first and second substrate and bonding together in vacuum condition; and then exposing, developing to remove the adhesion layer in the area of die opening window; it also can use the non-photo type adhesion materials and using the laser method to remove the adhesion material; Drilling several through holes, in the area except die opening window, from top of the second substrate to bottom of the first substrate; Cleaning the substrate and then blanket coating the seed metal on the surface of bonded substrate; Using PR to define the plating area; E-plating to form Cr/Ni/Au, Cu/Ni/Ag, or Cu/Ni/Al metal layers on top of the die metal pad, the sidewall of the die opening window, and the inner sidewall of through holes, then stripping the PR and etching the seed metal to form the metal pattern.

According to a certain embodiment of the invention, the coating techniques for the seed metal includes sputtering, evaporation, CVD (chemical vapor deposition); and the material of adhesion layer between two substrates includes liquid type and dry film type.

### BRIEF DESCRIPTION OF THE DRAWINGS

The above objects, and other features and advantages of the present invention will become more apparent after reading the following detailed description when taken in conjunction with the drawings, in which:

FIG. 1A illustrates a cross-sectional view of the substrate according to the present invention.

FIG. 1B illustrates a cross-sectional view of the substrate with tilted sidewall of the opening window according to the present invention.

FIG. 1C illustrates a cross-sectional view of the substrate with hollow through holes covered with the conductive metal according to the present invention.

FIG. 2A illustrates a cross sectional view of the substrate carrying a LED and encapsulated with a lens according to the present invention.

FIG. 2B illustrate a cross sectional view of the substrate carrying an LED and electrically connected to wiring circuits through RDL (redistribution layer)

FIG. 2C illustrates a cross sectional view of another type of substrate carrying an LED and encapsulated with a lens according to the present invention.

FIG. 3 illustrates the process step for forming the substrate according to the present invention.

FIG. 4 illustrates the cross section view of the bonded substrate according to the present invention.

FIG. 5 illustrates the cross section view of the bonded substrate with the adhesive layer stripped according to the present invention.

FIG. 6 illustrates the cross section view of the bonded substrate with through holes drilled according to the present invention.

FIG. 7 illustrates the cross section view of the bonded substrate with cavity metal coated to the present invention.

FIG. 8 illustrates the process step for attaching the LED chip into the bonded substrate according to the present invention.

FIG. 9A illustrates the process step for connecting the LED chip to the wiring circuit by wire bonding according to the present invention.

FIG. 9B illustrates the process step for connecting the LED chip to the wiring circuit by RDL according to the present invention.

FIG. 10 illustrates the process step for attaching a lens onto the top of the substrate.

### DETAILED DESCRIPTION

Structure and method for manufacturing a substrate for an Optical device is described below. In the following description, more detail descriptions are set forth in order to provide a thorough understanding of the present invention and the scope of the present invention is expressly not limited expect as specified in the accompanying claims.

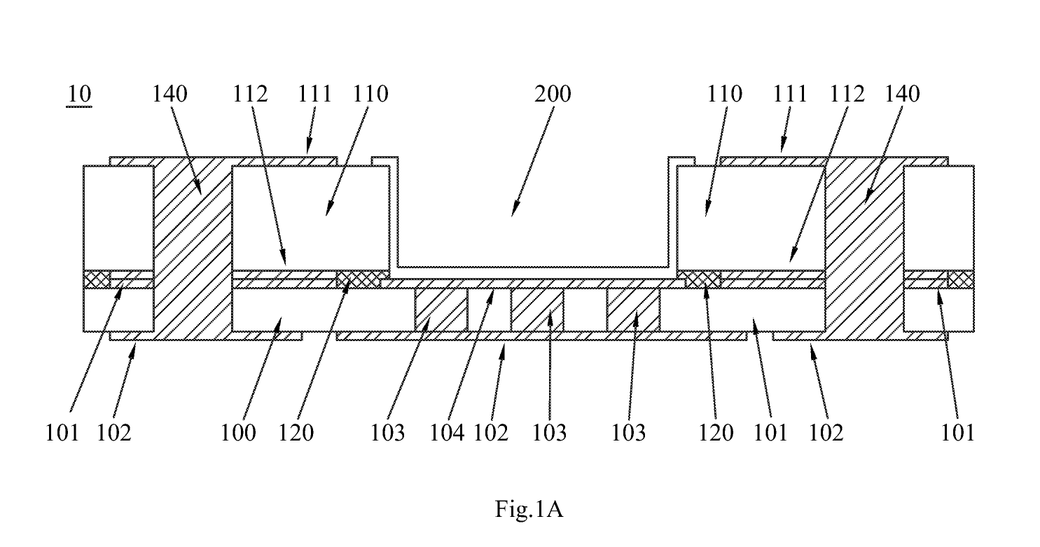

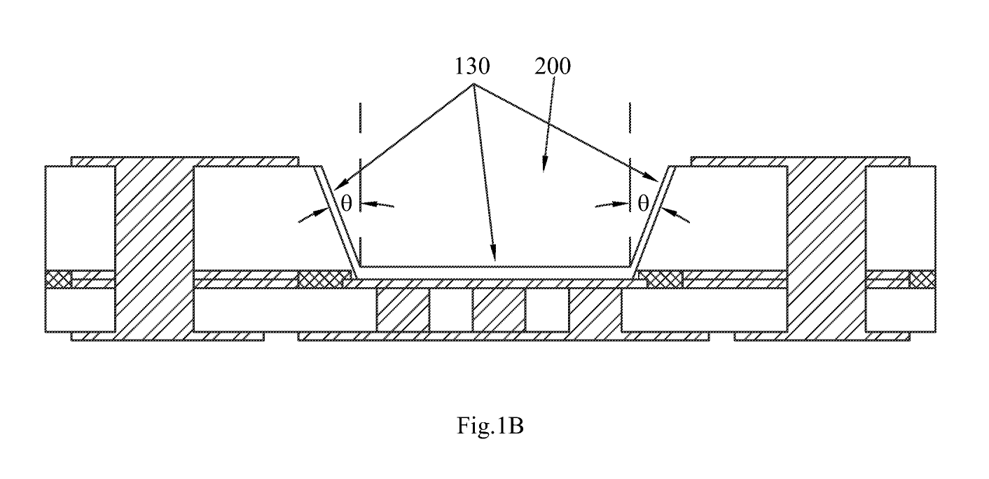

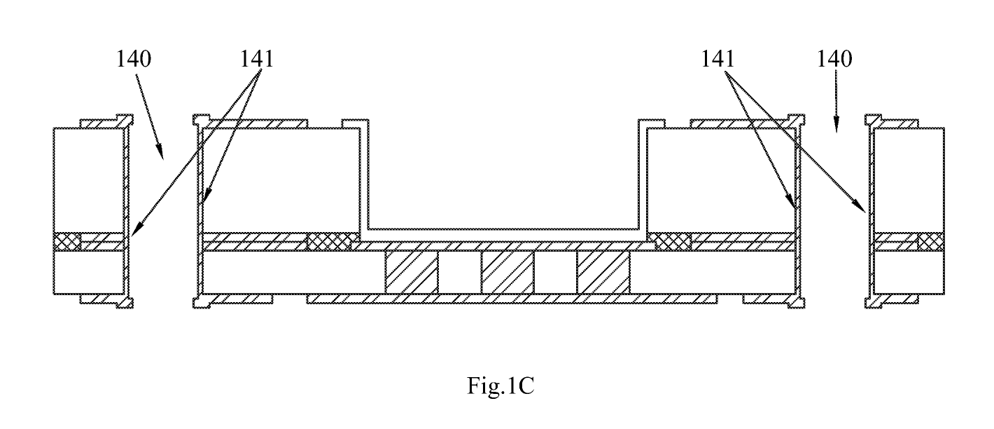

A substrate structure 10 with a cavity for carrying an optical device, such as LED (lighting emitting diode), Laser Diode, Photo Diode, Photo detector etc, is disclosed. As shown in FIG. 1A, the substrate structure 10 includes a first substrate 100 and a second substrate 110. The first substrate 100 has a die metal pad 104 for carrying an LED, a first wiring circuit 101 is on the top surface of the first substrate 100, while a second wiring circuit 102 is on the bottom surface of the first substrate 100, and a plurality of via holes 103 are filled with metal, alloy such as Cu or the like.

The second substrate 110 has a die opening window 200 to place an LED, the die opening window 200 substantially aligns with the plurality of via holes 103 as shown in the FIG. 1A. A third wiring circuit 111 is formed on the top surface of the second substrate 110, and a fourth wiring circuit 112 is formed on the bottom surface of the second substrate 110 which is between the via holes 103 and the die opening window 200. An adhesive layer 120 is placed adjacent to the corners of the die opening window 200 and between the first substrate 100 and the second substrate 110 to bond these two substrates together. Several through holes 140 were drilled from the first substrate 100 to the second substrate 110 and were filled with conductive materials such as Cu, Al, or the combination to electrically couple the first, second, third, and fourth wiring circuit 101,102, 111, and 112. The material of the die metal pad 104 and the first, second, third, and fourth wiring circuits 101, 102, 111, and 112 comprises but not limited to Al or Cu or the combination thereof. The material of the first and second substrate 110 and 111 comprises but not limited to FR4, FR5, BT, PI, silicon, glass, alloy 42, quartz or ceramic.

In one embodiment, as shown in FIG. 1B, the cavity metal 130 was coated on the surface of the inner wall of the die opening window 200 and on the top of die metal pad 104 as a reflector to enhance the light emitting efficiency. The wall of said die opening window 200 can tilt with an angle θ, preferably with 45 degree, for better reflecting the light out.

In one embodiment, as shown in FIG. 1C, the through holes are hollow and the inner walls of the through holes are coated with the conductive metal 141, such as Cu/Ni/Au, Cu/Ni/Ag and Cu/Ni/Al.

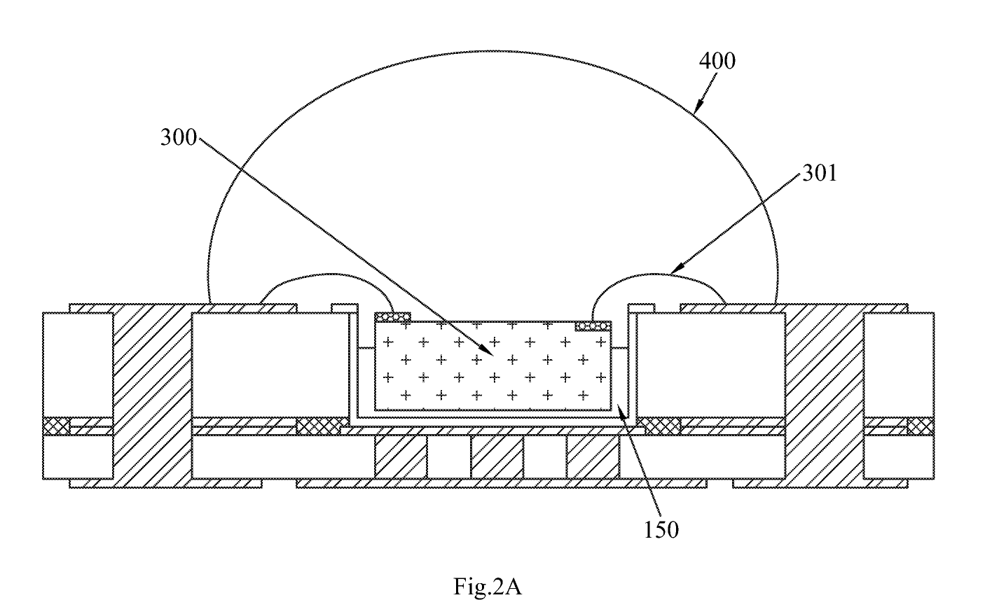

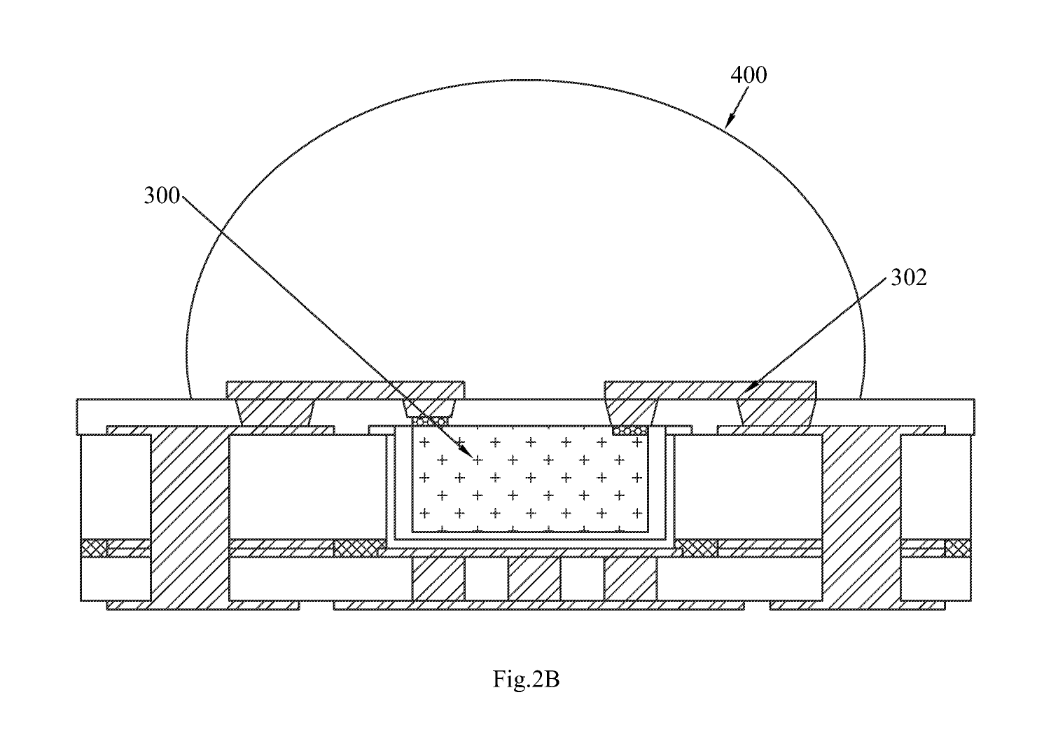

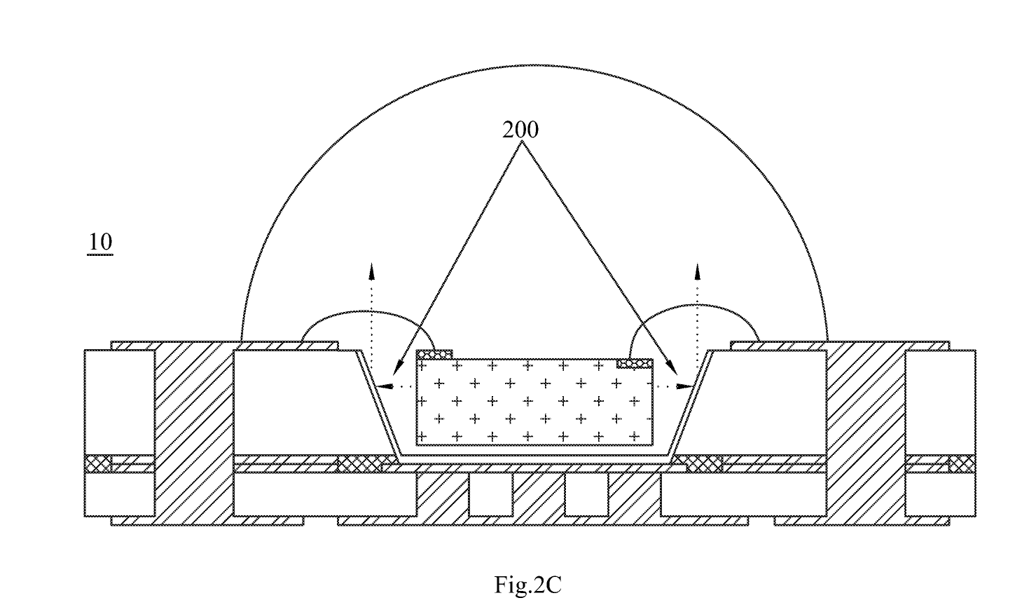

In on embodiment of the present invention, as shown in FIG. 2A, a LED chip is disposed within the die opening window 200 and thereon a lens 400 is attached. To assemble the package, a die attached material 150 is filled into the die opening window 200 and thereon the chip is placed and electrically connected to the third wiring circuit 111 by wire-bonding 301 or RDL (redistribution layer) 302, as shown in FIG. 2B. The preferable thickness of the die attached material 150 is around 10 um˜30 um. In another embodiment of the present invention, as shown in FIG. 2C, the substrate 10 with tilted wall around the die opening window 200 is used to improve the emitting efficiency.

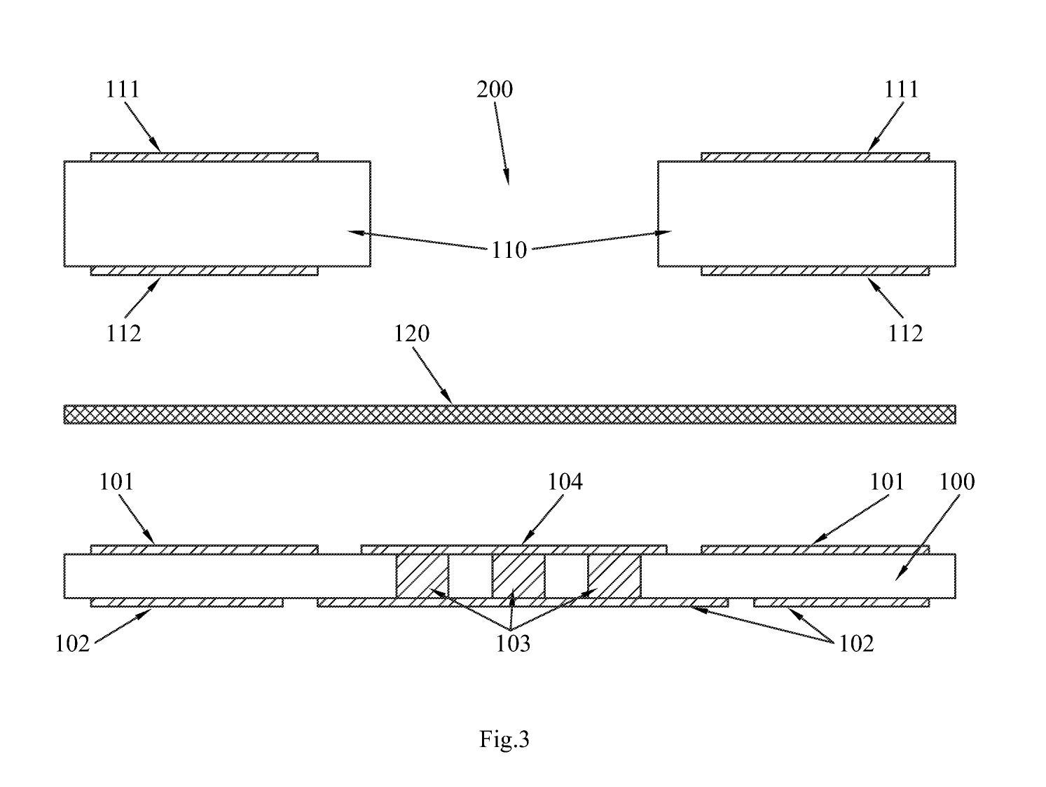

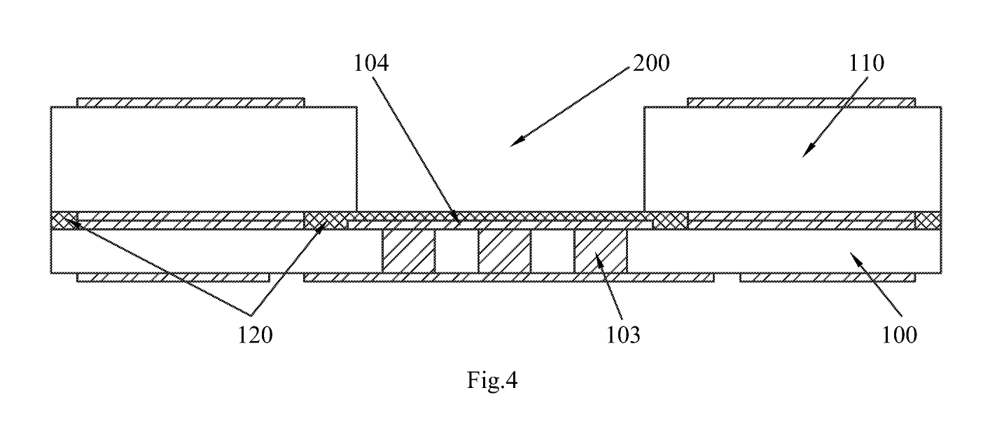

The process for the present invention is described as follows: As shown in FIG. 3, preparing the first substrate 100 with the die metal pad 104, the first and second 101 and 102 wiring circuits, and the via holes 103. Preparing the second substrate 110 with the third and fourth 111 and 112 wiring circuits, and a Puncher or Laser is employed to make the die opening window 200 on the second substrate 110. The adhesive layer 120 is placed between the top of the first substrate 100 and the bottom of the second substrate 110. As shown in FIG. 4, the top of the first substrate 100 and the bottom of second substrate 110 are bounded together through the adhesive layer 120 by vacuum bonding.

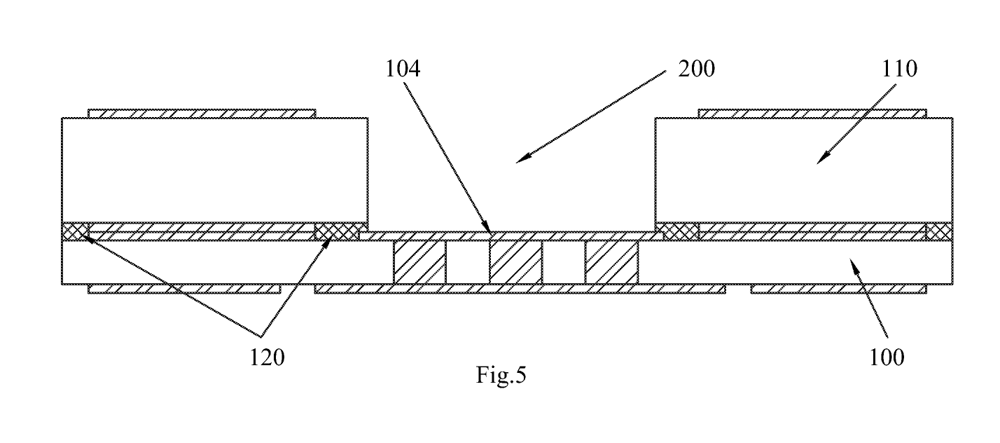

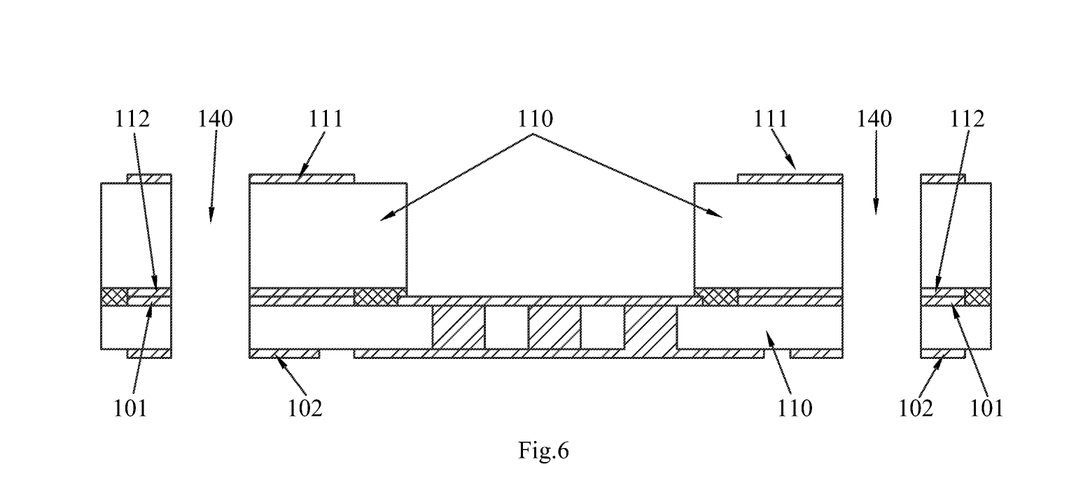

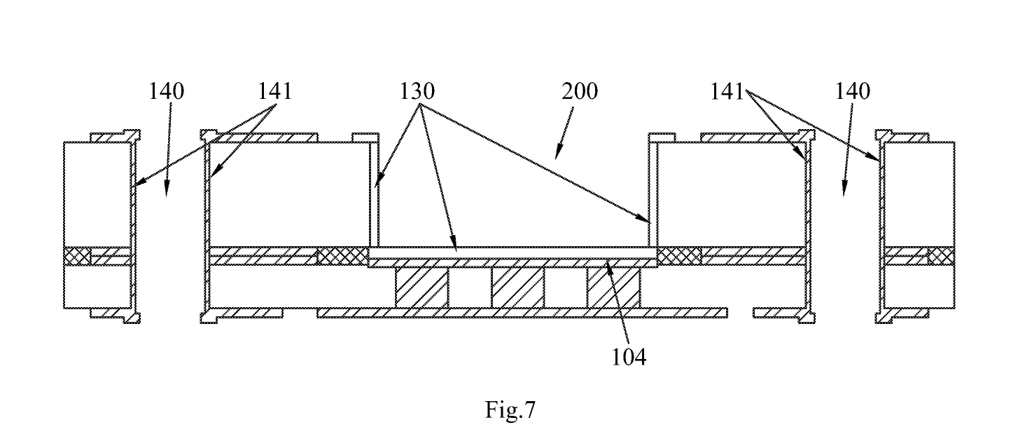

Referring to FIG. 5, the steps of laser, or exposing, and developing (photo sensitive material) are also required, not shown in the Figure, to remove the adhesive layer 120 on the die metal pad 104. As shown in FIG. 6, the through holes 140 are formed by drilling from the third wiring circuits 111 on the second substrate 110 to the second wiring circuits 102 on the first substrate 100. The substrate 10 is clean and then blanket sputtering is used to form a seed metal on the surface of the bonded substrate 10. PR is utilized to define the plating area and then the PR is stripped and the seed metal is removed except on the die metal pad 104 by etching. Also, as shown in FIG. 7, electro plating (E-plating) is performed to form the conductive metal 141 on the surface of the through holes 140, and the cavity metal 130 on the sidewall of the die opening window 200 and the top of die metal pad 104. The material of said conductive metal 141 and said cavity metal 130 comprises Cu/Ni/Au, Cu/Ni/Ag, and Cu/Ni/Al.

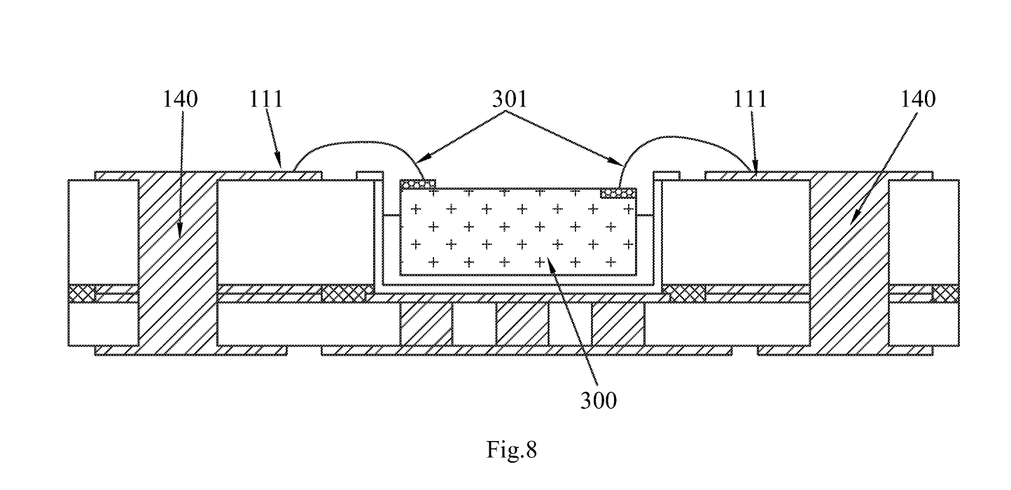

As shown in FIG. 8, the die attached material 150 is dispensed (or film tape) on the bottom area of the die opening window 200, and then bonding the chip 300 with force to attach the chip into the die opening window 200. The die bonding force is controlled to keep the thickness of the die attached material 150 between the backside of said chip 300 and the top of the die metal pad 104 around 10 um˜30 um. Also, the through holes 140 are filled with Cu by using E-plating or printing method.

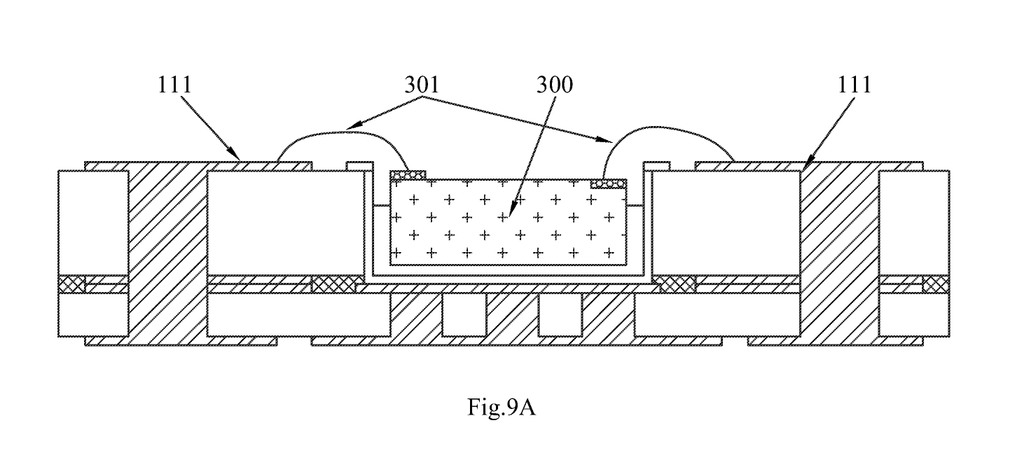

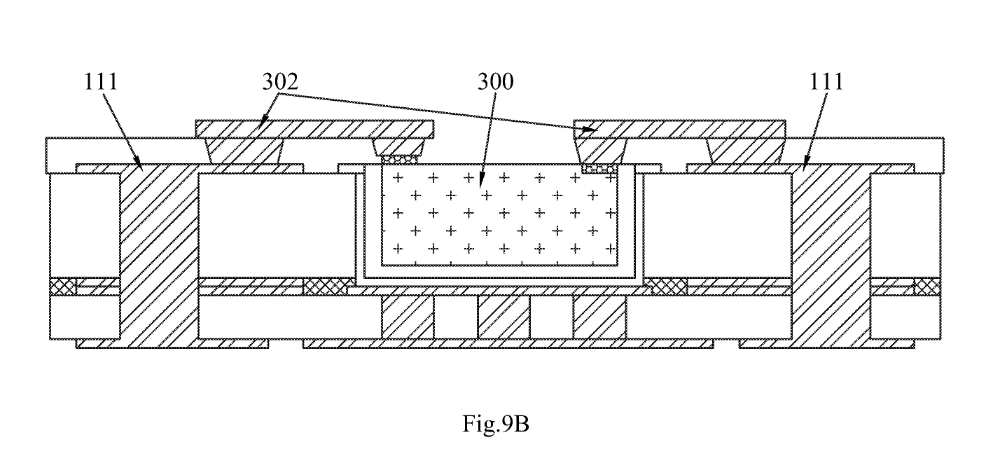

Then, as shown in FIG. 9A, the anode and cathode pad of the chip 300 is connected to the third wiring circuit 111 by wire bonding 301. In another embodiment, the electrical connection between the chip 300 and the third wiring circuit 111 is implemented by RDL (redistribution layer) 302, as shown in FIG. 9B.

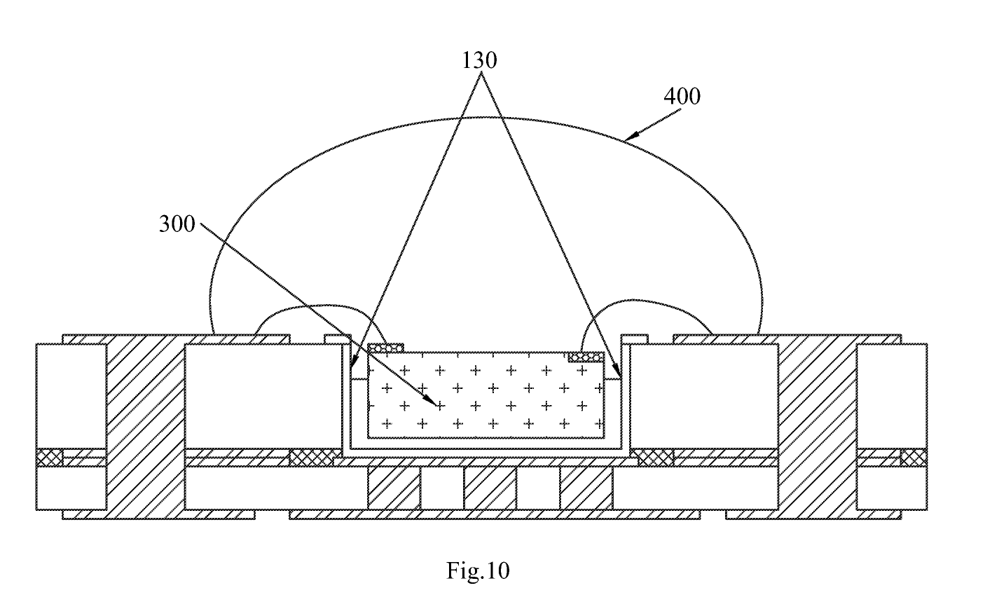

Finally, as shown in FIG. 10, a lens 400 is attached onto the top of the second substrate 110 to protect the chip 300 and to converge light from the chip 300 and the cavity metal 130.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of an optical device package comprising:
a first substrate with a die metal pad, a first wiring circuit on a top surface of said first substrate, and a second wiring circuit on a bottom surface of said first substrate;
a second substrate with a die opening window, a third wiring circuit on a top surface of said second substrate and a fourth wiring circuit on a bottom surface of said second substrate;
an adhesive material between said top side of said first substrate and said bottom side of said second substrate except said die opening window; and
a cavity metal covering on a wall of said die opening window of said second substrate and said top side of said die metal pad of said first substrate within said die opening window

2. The structure of claim 1, further comprising a plurality of via holes under said die metal pad; wherein said plurality of via holes is filled with Cu.

3. The structure of claim 1, further comprising a plurality of through holes connect between wiring circuits of said first and second substrate; and a conductive metal formed on an inner wall of said through holes.

4. The structure of claim 3, wherein said conductive metal is selected from the group consisting of Cu/Ni/Au, Cu/Ni/Ag, Cu/Ni/Al and the combination thereof.

5. The structure of claim 1, further comprising an optical chip attached into said die opening window and on said cavity metal and on said die metal pad of said first substrate.

6. The structure of claim 1, further comprising a die attached material filled into a gap between the backside of said optical chip and a top of said cavity metal and the die metal pad of said first substrate, and between a sidewall of said optical chip and said wall of said die opening window.

7. The structure of claim 5, further comprising wires or RDL connected between metal pads of said optical chip and said third wiring circuit of said second substrate.

8. The structure of claim 7, further comprising a lens on top of said optical chip area.

9. The structure of claim 6, wherein a thickness of said die attached material between backside of said optical chip and top of said cavity metal on die metal pad is less than 30 um.

10. The structure of claim 1, wherein a material of said wiring circuits on said first and second substrate includes Cu, Al or the combination thereof.

11. The structure of claim 1, wherein a material of said die metal pad on said first substrate includes Cu, Al or the combination thereof.

12. The structure of claim 1, wherein a material of said cavity metal includes Ag, Au, Al or the combination thereof.

13. The structure of claim 1, wherein a material of said first and second substrate includes BT, FR5, FR4 or PCB (printed circuit board) materials.

14. The structure of claim 1, wherein a material of said first and second substrate includes silicon, Glass, ceramic or metal.

15. A method of forming a substrate for an optical chip comprising:
preparing the first substrate with the wiring circuits on both side, the die metal pad on top side, and several via holes under said die metal pad;
preparing said second substrate with the wiring circuits on both side;
cutting said second substrate to form said die opening window area by a puncher or a Laser;
placing an adhesion material between said first and said second substrate;
bonding said first and second substrate with said adhesive material in vacuum condition;
to remove said adhesive material on top of said die metal pad;
drilling said first and second substrate to form through holes within said first and second substrate;
cleaning and then coating a seed metal layer on a surface of said bonded substrate;
defining a plating area by using a photo resistance;
forming said cavity metal and a conductive metal on an inner wall of said through holes by plating;
Stripping said photo resistance and etching said seed metal layer.

16. The method of claim 15, wherein said adhesion material includes liquid type and dry film type.

17. The method of claim 15, wherein the technique of coating said seed metal layer includes sputtering, evaporation or CVD (chemical vapor deposition).

18. The method of claim 15, wherein said conductive metal includes Cu/Ni/Au, Cu/Ni/Ag or Cu/Ni/Al.
